(19) United States
(12) Patent Application Publication
(10) Pub. No.: US 2025/0029901 A1
(43) Pub. Date: Jan. 23, 2025

(54) COMPACT DIRECT-BONDED METAL SUBSTRATE PACKAGE

(71) Applicant: SEMICONDUCTOR COMPONENTS INDUSTRIES, LLC, Scottsdale, AZ (US)

(72) Inventors: Silnore Tejero SABANDO, Lapulapu City (PH); Chee Hiong CHEW, Seremban (MY)

(73) Assignee: SEMICONDUCTOR COMPONENTS INDUSTRIES, LLC, Scottsdale, AZ (US)

(21) Appl. No.: 18/353,148

(22) Filed: Jul. 17, 2023

(51) Int. Cl. H01L 23/495; H01L 21/48; H01L 23/498

(52) U.S. Cl. CPC H01L 23/49513; H01L 21/4825; H01L 23/4952; H01L 23/49872

(57) ABSTRACT

A compact power inverter is efficiently laid out on a multi-layer direct bond metal (DBM) structure, having a reduced footprint and straight, short-run wire bonds. The compact layout reduces an amount of material needed to fabricate a multi-layer DBM that includes a silicon nitride ceramic layer. The layout is further designed so that wire bonds can be routed without bending around corners. The compact DBM structure and short wire bonds provide a solution that is both low-cost and highly reliable.

### TECHNICAL FIELD

This description relates to assembling and packaging semiconductor device modules, semiconductor device assemblies, and semiconductor devices. More specifically, this description relates to semiconductor device modules in which components are arranged in a compact layout.

### BACKGROUND

Semiconductor device assemblies, e.g., chip assemblies, that include power semiconductor devices can be implemented using multiple semiconductor dies, substrates (e.g., die attach pads (DAPs)), electrical interconnections, and a molding compound. Power transistors can include, for example, insulated-gate bipolar transistors (IGBTs), power metal-oxide-semiconductor field effect transistors (MOSFETs), and so forth. Fast recovery diodes (FRDs) may be used in conjunction with power transistors. Electrical interconnections within a high-power semiconductor device module can include, for example, bond wires, conductive spacers, and conductive clips. A polymer molding compound can serve as an encapsulant to protect components of the device assembly. Such high-power chip assemblies, encapsulated as semiconductor device modules, can be used in various applications, including electric vehicles (EVs), hybrid electric vehicles (HEVs), and industrial applications.

### SUMMARY

In some aspects, the techniques described herein relate to an apparatus, including: a substrate; a lead frame attached to the substrate, the lead frame having a gate lead frame post, a sense lead frame post, and a ground connection; a direct bond metal (DBM) structure on the substrate, the DBM structure including a silicon nitride based ceramic layer; a first die and a second die attached side-by-side to the DBM structure; a U-shaped metal clip coupling top sides of the first die and the second die to the lead frame using solder; and wire bonds coupling gate terminals of the first die and the second die directly to the gate lead frame post.

In some aspects, the techniques described herein relate to an apparatus, further including a wire bond coupling a sense terminal of the second die to the sense lead frame post.

In some aspects, the techniques described herein relate to an apparatus, further including an arm of the metal clip coupling a sense terminal of the second die to the sense lead frame post.

In some aspects, the techniques described herein relate to an apparatus, wherein the metal clip is connected to the ground connection.

In some aspects, the techniques described herein relate to an apparatus, including: A substrate; a lead frame portion on the substrate; a direct bond metal (DBM) structure on the substrate, the DBM structure including a first metal layer, a second metal layer, and a ceramic layer disposed between the first metal layer and the second metal layer, a gate pad and a die pad defined within the first metal layer; a first die and a second die attached side-by-side to the die pad of the DBM substrate;

In some aspects, the techniques described herein relate to a U-shaped metal clip having a first tab coupled to a top side of the first die and having a second tab coupled to a top side of the second die, the U-shaped metal clip having a third tab coupled (on an opposite end of the U-shaped metal clip the first tab and the second tab) to the lead frame portion; and wire bonds, including a first wire bond coupling a gate terminal of the first die to a gate terminal of the second die, and a second wire bond coupling the second die to the gate pad.

In some aspects, the techniques described herein relate to an apparatus, further including another wire bond coupling a sense terminal of the second die to a sense lead frame post.

In some aspects, the techniques described herein relate to an apparatus, wherein the wire bonds further include a third wire bond coupling the gate pad to the gate lead frame post.

In some aspects, the techniques described herein relate to an apparatus, wherein the first wire bond extends in a transverse direction with respect to the gate lead frame post.

In some aspects, the techniques described herein relate to an apparatus, wherein length and width dimensions of the DBM are each less than 15 mm.

In some aspects, the techniques described herein relate to an apparatus, wherein the wire bonds are made of 300 μm aluminum wire.

In some aspects, the techniques described herein relate to an apparatus, wherein the first die and the second die include silicon carbide (SiC).

In some aspects, the techniques described herein relate to a method, including: attaching back sides of a first die and a second die to a direct bond metal (DBM) structure; forming a lead frame and a metal clip; attaching the DBM structure to a substrate; attaching the metal clip between top sides of the first die and the second die and a ground plate of the lead frame; coupling gate terminals of the first and second dies to a first lead frame post; and coupling a sense terminal of the second die to a second lead frame post.

In some aspects, the techniques described herein relate to a method, wherein coupling the gate terminals to the first lead frame post includes use of wire bonds.

In some aspects, the techniques described herein relate to a method, wherein coupling the gate terminals to the first lead frame post includes coupling the gate terminal of the first die directly to the gate terminal of the second die and coupling the gate terminal of the second die to the first lead frame post.

In some aspects, the techniques described herein relate to a method, wherein coupling the gate terminal of the second die to the first lead frame post includes coupling the gate terminal of the second die to a gate pad and coupling the gate pad to the first lead frame post.

In some aspects, the techniques described herein relate to a method, wherein coupling the sense terminal to the second lead frame post includes use of a wire bond.

In some aspects, the techniques described herein relate to a method, wherein coupling the sense terminal to the second lead frame post includes use of a tab of the metal clip.

In some aspects, the techniques described herein relate to a method, wherein forming the metal clip includes forming the metal clip from copper.

In some aspects, the techniques described herein relate to a method, wherein forming the lead frame includes forming the lead frame from copper.

In some aspects, the techniques described herein relate to a method, further including encapsulating the substrate in a package, wherein a back side of the package exposes a lower layer of the DBM structure.

### BRIEF DESCRIPTION OF THE DRAWINGS

FIG. 1 is a perspective view of a compact power module, according to a first implementation of the present disclosure.

FIG. 2 is a top side plan view of the compact power module shown in FIG. 1, according to implementations of the present disclosure.

FIG. 3 is a back side plan view of the compact power module shown in FIG. 1, according to implementations of the present disclosure.

FIG. 4A is a perspective view of a compact power module according to a second implementation of the present disclosure.

FIG. 4B is a perspective view of a compact power modules according to a third implementation of the present disclosure.

FIGS. 5A and 5B are top side plan views of the compact power modules shown in FIGS. 4A and 4B, respectively, according to implementations of the present disclosure.

FIG. 6 is a back side plan view of a compact power module according to implementations of the present disclosure.

FIG. 7 is a flow diagram illustrating a method of fabricating a compact power module, according to implementations of the present disclosure.

Aspects of the present disclosure are best understood from the following detailed description when read with the accompanying figures. It is noted that, in accordance with common practice in the industry, various features are not necessarily drawn to scale. Dimensions of the various features may be arbitrarily increased or reduced for clarity of discussion. In the drawings, like reference symbols may indicate like and/or similar components (elements, structures, etc.) in different views. The drawings illustrate generally, by way of example, but not by way of limitation, various implementations discussed in the present disclosure. Reference symbols shown in one drawing may not be repeated for the same, and/or similar elements in related views. Reference symbols that are repeated in multiple drawings may not be specifically discussed with respect to each of those drawings but are provided for context between related views. Also, not all like elements in the drawings are specifically referenced with a reference symbol when multiple instances of an element are illustrated.

### DETAILED DESCRIPTION

The footprint of electronic devices is important with respect to materials cost and reliability. When electronic devices are laid out in an inefficient manner, wasted space on a substrate increases material cost unnecessarily. In addition, wiring between devices that are spaced apart can be inherently more vulnerable to damage or breakage and consequently, can cause reliability failures. These concerns are particularly significant for high power modules that include expensive materials such as silicon carbide (SiC), high tech ceramics made of silicon nitride (Si₃N₄), and direct bond metal (DBM) structures, e.g., direct bond copper (DBC) structures. When these high power modules are manufactured in large volume, even a small reduction in per unit cost can add up to a substantial saving, in the millions of dollars.

This disclosure relates to implementations of a compact power inverter that is efficiently laid out on a multi-layer DBC structure, with a reduced footprint and short-run wire bonds. Although the overall package may be large, the compact DBC structure and short wire bonds provide a solution that is both low-cost and highly reliable. Shrinking the injection molded package as well may not be cost effective, due to design and process changes that could outweigh the cost savings of fewer, relatively inexpensive, plastic materials needed for a smaller package. Consequently, the compact power inverter may be housed in what appears to be an oversized package. Although the implementations described herein are directed to packaging of a circuit related to a power inverter, other types of circuits can be included in the packaging configurations described herein.

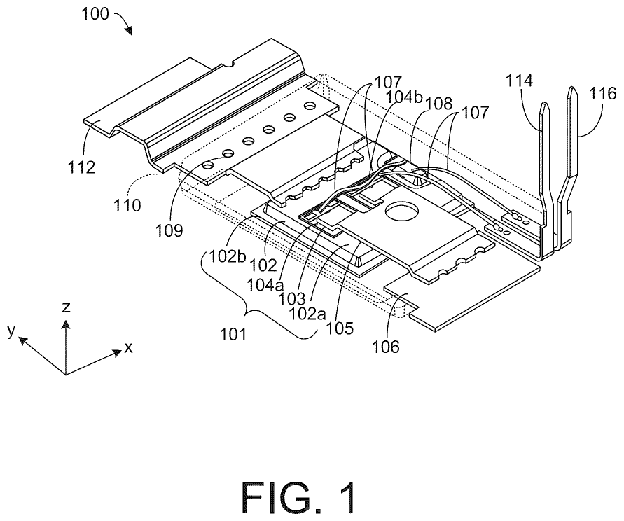

FIG. 1 is a perspective view of a high-power semiconductor device module, or compact power module 100, in accordance with a first implementation of the present disclosure. In some implementations, the compact power module 100 includes a high-power semiconductor chip assembly, or compact electronic power assembly 101. The compact electronic power assembly 101 includes a single-sided direct bond metal (DBM) structure 102, a die attach pad (DAP) 102a, and one or more electronic components, e.g., semiconductor dies, or chip assemblies, 104 (two shown). The chip assemblies 104 are attached to, e.g., mounted on, or coupled to, a top surface of the die attach pad 102a by a bonding agent, e.g., an epoxy, a solder, a silver (Ag) sintering material, and/or an adhesive. In some implementations, the compact electronic power assembly 101 operates at 650 Volts and 200 Amps.

In some implementations, the DBM structure 102 can be a direct bond copper (DBC) type structure, a direct plating copper (DPC) type structure, or a direct bond aluminum (DBA) type structure. The DBM structure 102 may be referred to as a heat spreader that provides single-sided or double sided cooling of the compact electronic power assembly 101. In some implementations, the DBM structure 102 has a thickness in a range of about 0.5 mm to about 3.0 mm. In some implementations, the direct bond metal (DBM) structure 102 is designed as a three-layer DBM structure that includes upper and lower metal layers separated by a dielectric layer. In some implementations, the dielectric layer serves as a thermal mass disposed between the two outer metal layers to draw in and absorb heat. The dielectric layer also provides electrical insulation between the upper and lower metal layers of the DBM structure. In some implementations, the dielectric layer can be a ceramic, e.g., silicon nitride (Si₃N₄) or aluminum oxide (Al₂O₃), Si₃N₄ being a significantly more expensive ceramic material than Al₂O₃.

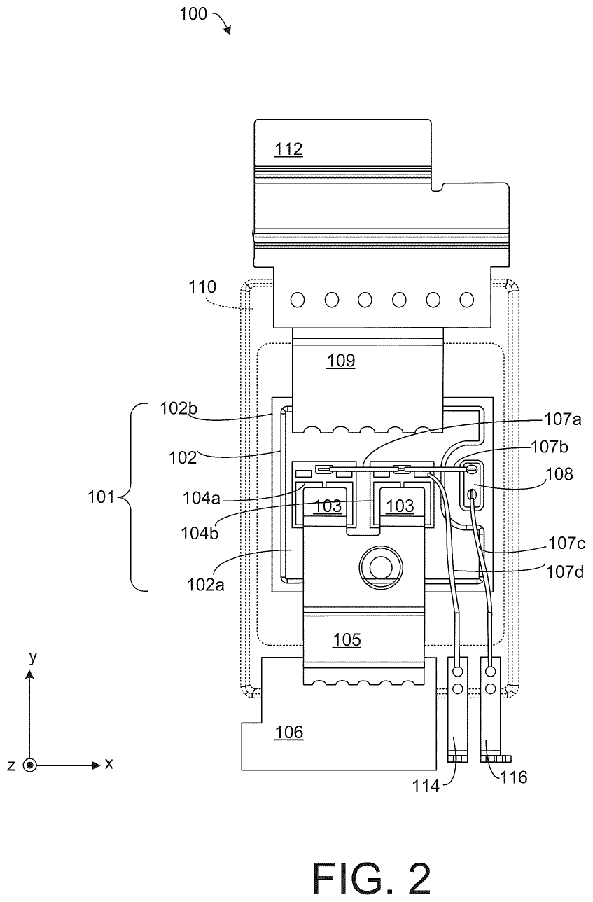

A central area of the compact electronic power assembly 101 includes the die attach pad (DAP) 102a to which the chip assemblies 104 are mounted. In some implementations, the die attach pad 102a can be formed by the upper metal layer of the DBM structure 102. The die attach pad 102a, as shown in FIG. 2, can include a cut-out, e.g., on the right side to accommodate a landing pad for wire bond connections. In some implementations, the dielectric layer and/or the bottom metal layer of the DBM can have a larger footprint than the die attach pad 102a.

In some implementations, the chip assemblies 104 can include, for example, an iGBT (transistor) semiconductor die as shown on the left side, and an FRD (diode) semiconductor die as shown on the right side. However, other types of semiconductor dies can be used as one or more of the chip assemblies 104 in the compact electronic power assembly 101. In some implementations, the term “chip assemblies 104” can refer to a single semiconductor die. The chip assemblies 104 can fabricated on various types of semiconductor substrates, e.g., semiconductor wafers, for example, silicon (Si), silicon carbide (SiC), gallium (Ga), gallium nitride (GaN), aluminum gallium nitride (AlGaN), gallium arsenide (GaAs), aluminum gallium arsenide (AlGaAs), indium phosphide (InP), glass substrates, sapphire substrates, and so on. In some implementations, the chip assemblies 104 can be fabricated on different substrates. For example, an iGBT chip assembly 104a can be fabricated on a silicon substrate of semiconductor die 104a, while an FRD chip assembly 104b can be fabricated on a SiC substrate. In some implementations, the chip assemblies 104 are both fabricated on a SiC substrate.

In some implementations, the compact power module 100 further includes a U-shaped clip 105, a lead frame 106, wire bonds 107 (four shown), an island 108, a mounting bracket plate 109, and a mounting bracket 112 (which in some implementations can be a lead frame extension or can be part of a lead frame). In some implementations, the lead frame 106, the U-shaped clip 105, the mounting bracket 112, and the lead posts 114 and 116 can be cut or stamped from a thin, rolled sheet of metal, e.g., copper.

The U-shaped clip 105 couples the chip assemblies 104 directly to the lead frame 106. The U-shaped clip 105 provides mechanical and electrical connections to terminals of the diode and transistor devices on board the chip assemblies 104. The U-shaped clip 105 also serves to dissipate heat from the chip assemblies 104. In some implementations, the U-shaped clip 105 can include tabs 103 (two shown) separated by a break. The tabs 103 can extend out from a main body of the U-shaped clip 105, along a longitudinal direction of the compact power module 100, e.g., aligned with the y-axis (between mounting bracket 112 and the lead frame 106), to provide separate connections to different terminals of a device within the IGBT chip assembly 104. In some implementations, the U-shaped clip 105 can be contoured so as to conform to a step up from the lead frame 106, over the DBM 102, and step down to the level of the chip assemblies 104. The contours of the U-shaped clip 105 are spaced apart from the DBM structure 102 so that the U-shaped clip 105 and the die attach pad 102a are not in physical or electrical contact.

The wire bonds 107 couple semiconductor devices on the chip assemblies 104 to lead posts 114 and 116, either directly or via the island 108. In some implementations, the wire bonds 107 are made of 300 μm diameter aluminum wire. The island 108 can be located in a cut-out formed by the boundary of the die attach pad 102a. The cut-out yields a DBM in which the shape of the die attach pad 102a may resemble a U-shape in a direction orthogonal to that of the U-shaped clip 105 (e.g., tabs of the U-shaped clip 105). The lead posts 114 and 116 provide signal paths from the compact packaged electronic power assembly 101 to external devices, power supplies, and ground connections.

The mounting bracket 112 can be used to mount the compact power module 100 to a heat sink (not shown). The mounting bracket plate 109 provides mechanical coupling between the mounting bracket 112 and the DAP 102a. Because of the compact size of the DBM structure 102, the mounting bracket plate 109 can be elongated (or have an elongated shape) to traverse the increased distance between the mounting bracket 112 and the DBM structure 102. In some implementations, the mounting bracket plate 109 can extend up to about half the length of the encapsulant 110. The mounting bracket plate 109 and/or the mounting bracket 112 can be shaped to include one or more bends, to permit an exterior portion of the mounting bracket 112 to be substantially co-planar with an exterior portion of the lead frame 106. In some implementations, the mounting bracket plate 109 can be integral to the mounting bracket 112.

The compact electronic power assembly 101, U-shaped clip 105, wire bonds 107, island 108, mounting bracket plate 109, a portion of the lead frame 106, and a portion of the mounting bracket 112 can be encapsulated by an encapsulant 110 to complete formation of the compact power module 100. In some implementations, the encapsulant 110, e.g., a polymer material, can be an epoxy molding compound (EMC) that serves to seal and protect various components of the compact electronic power assembly 101.

FIG. 2 is a top side plan view of the compact power module 100, showing the layout, relative sizes, and connections between the various components thereof, in accordance with the first implementation of the present disclosure. Due to the efficient layout of the compact electronic power assembly 101, the DBM structure 102 occupies only about half of the interior space within the encapsulated package defined by the encapsulant 110. In some implementations, the compact electronic power assembly 101 has dimensions of about 13 mm×15 mm, or an area in the range of about 190 mm² to about 200 mm². These dimensions are about 40% smaller than current designs used in power inverters, while delivering equivalent thermal performance, according to simulation results. Shrinking the dimensions of the DBM structure 102 reduces the cost commensurately, by about 40%.

In the layout shown, the chip assembly 104a and the chip assembly 104b are arranged side-by-side, with each die in a vertical position, allowing for direct wire bond connections. The island 108 serves as a connection pad, e.g., gate pad, that re-routes horizontal wire bonds 107a and 107b to a vertical wire bond 107c. Thus, with the island 108, 90-degree bends in wire bonds can be avoided, for enhanced reliability. The wire bond 107a couples a gate terminal of the chip assembly 104a to a gate terminal of the chip assembly 104b. Wire bond 107b couples the gate terminal of the chip assembly 104b to a first terminal on the island 108. Wire bond 107c connects a second terminal on the island 108 to the lead post 116. Wire bond 107d couples a sense terminal of the chip assembly 104b directly to the lead post 114. Wire bonds 107c and 107d extend along the longitudinal direction of the compact power module 100. This wire bond configuration thus described has fewer wires and shorter wire bond lengths than current designs used for power inverters.

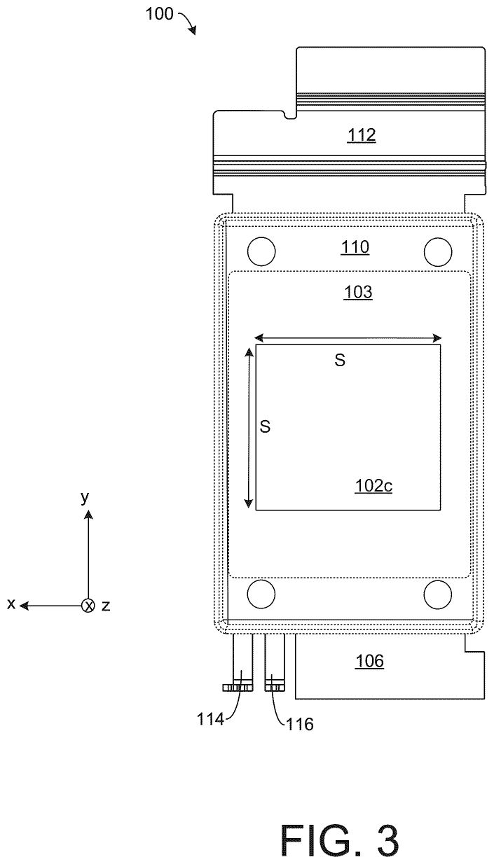

FIG. 3 is a back side plan view of the compact power module 100, in accordance with some implementations of the present disclosure. FIG. 3 shows exterior parts of the compact power module 100, including the encapsulant 110 and other parts that extend out from the encapsulant 110—the mounting bracket 112, the lead frame 106, and the lead posts 114 and 116, and a lower DBC layer 102c. The mounting bracket 112 and the lead frame 106 provide mechanical coupling at either end of the compact power module 100, while the lead posts 114 and 116 provide electrical coupling for the compact power module 100.

FIG. 3 further shows the compact DBM structure 102 is substantially square, having sides of length s. In some implementations, the three-layer DBM structure 102 is disposed in an opening in the encapsulant 110, so that the lower DBC layer 102c is exposed on the back side of the compact power module 100. It is noted that the upper DBC layer, serving as a die attach pad 102a, is exposed on the front side of the compact power module 100, as shown in FIG. 2. The DBM structure 102 therefore can radiate heat from both the back side and the front side of the compact power module 100, acting as a double-sided heat sink to dissipate heat produced by the compact electronic power assembly 101. The opening in the encapsulant 110 helps to ensure that radiated heat is not trapped in the package of the compact power module 100. In some implementations, enhanced thermal transfer through the back side can compensate for the smaller size of the DBM structure 102.

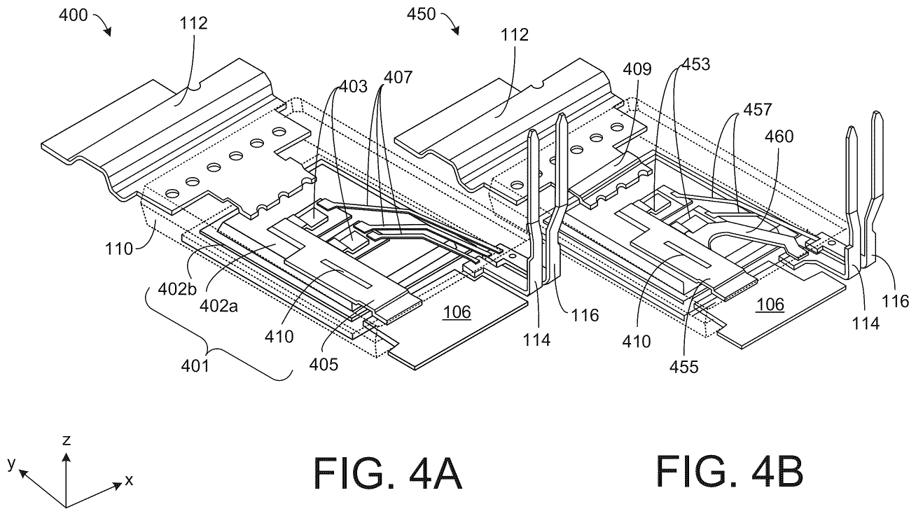

FIG. 4A is a perspective view of a compact power module 400, according to a second implementation of the present disclosure. The compact power module 400 is similar to the compact power module 100, in that it includes common parts such as the lead frame 106, the encapsulant 110, the mounting bracket 112, and the lead posts 114 and 116, arranged according to a similar design as in the compact power module 100. However, the compact power module 400 differs from the compact power module 100 in that a compact electronic power assembly 401 is substituted for the compact electronic power assembly 101. The compact electronic power assembly 401 includes a two-layer DBC 402 instead of the three-layer DBC 102, and an F-shaped clip 405 instead of a U-shaped clip 105. In addition, a mounting bracket plate 409 that couples the compact electronic power assembly 401 to the mounting bracket 112 has a different shape than the mounting bracket plate 109.

In some implementations, the compact electronic power assembly 401 occupies a larger area than the compact electronic power assembly 101, and the footprint of the compact electronic power assembly 401 is rectangular. However, the size of the compact electronic power assembly 401 is still small, relative to the size of the overall package. In some implementations, the compact electronic power assembly 401 is centered within the encapsulant 110. In some implementations, the mounting bracket plate 409 is narrower than the mounting bracket plate 109, and shorter, since there is less space between the mounting bracket 112 and the larger rectangular footprint of the compact electronic power assembly 401. In some implementations, the edge of the mounting bracket plate 409 that lands on the upper DBC layer 402a can be a wavy or scalloped edge. In some implementations, the mounting bracket plate 409 can be integral to the mounting bracket 112.

In some implementations, the compact electronic power assembly 401 provides a different solution for coupling chip assemblies 104 to the lead frame 106 and the lead posts 114 and 116. In particular, the compact electronic power assembly 401 includes a DBC 402, an F-shaped clip 405, and wire bonds 407 (three shown). In the compact electronic power assembly 401, the chip assemblies 104 are rotated clockwise by 90 degrees relative to the orientation of the chip assemblies 104 in the compact electronic power assembly 101. Consequently, the compact electronic power assembly 401 includes an F-shaped clip 405 aligned substantially along the same direction as the gate connections to the lead post 116. The F-shaped clip 405 has two tabs 403 extending in a direction transverse (e.g., aligned with the x-direction) to its main body, (e.g., aligned with the y-direction). In some implementations, the F-shaped clip 405 can include a slot 410 that may assist in releasing heat and may reduce the weight of the F-shaped clip 405.

FIG. 4B is a perspective view of a compact power module 450, according to a third implementation of the present disclosure. The compact power module 450 shares many features with the compact power module 400 shown in FIG. 4A, wherein a compact electronic power assembly 451 is substituted for the compact electronic power assembly 401. The compact electronic power assembly 451 has substantially the same rectangular footprint and the same DBC 402 as the compact electronic power assembly 401. As in FIG. 4A, the compact electronic power assembly is centered within the encapsulant 110.

The compact power assembly 451 provides another alternative solution for coupling chip assemblies 104 to the lead frame 106 and the lead posts 114 and 116. In particular, the compact electronic power assembly 451 includes an F-shaped clip 455, and wire bonds 457 (two shown) that differ from corresponding elements of the compact electronic power assembly 401. In the compact electronic power assembly 451, the chip assemblies 104 again are rotated clockwise by 90 degrees relative to the orientation of the chip assemblies 104 in the compact electronic power assembly 101, and the F-shaped clip 455 has two tabs 453 extending in a direction transverse (e.g., aligned with the x-direction) to its main body (e.g., aligned with the y-direction). In some implementations, the F-shaped clip 455 can include a slot 460 that may assist in releasing heat and may reduce the weight of the F-shaped clip 455. In addition, the F-shaped clip 455 includes an arm 462 that couples directly to the lead post 114.

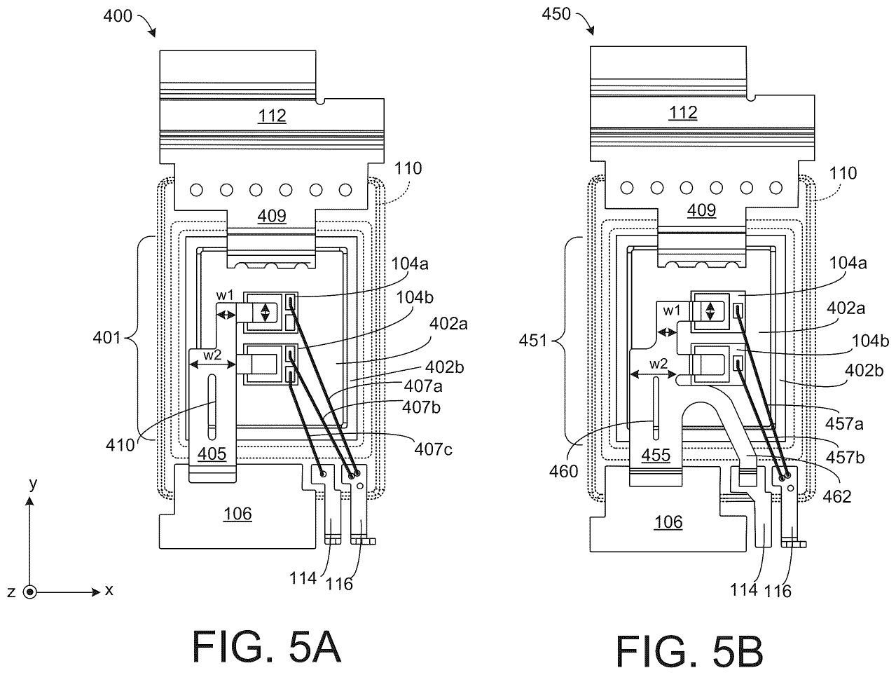

FIG. 5A is a top side plan view of the compact power module 400 shown in FIG. 4A, according to a second implementation of the present disclosure. FIG. 5A shows the layout, relative sizes, and connections between the various components thereof, in accordance with the second implementation of the present disclosure. In some implementations, the compact electronic power assembly 401 has rectangular dimensions L×s of about 17.5 mm×14.0 mm, or an area in the range of about 240 mm² to about 250 mm². These dimensions are about 30% smaller than current designs used in power inverters, while delivering equivalent thermal performance, according to simulation results. Shrinking the dimensions of the DBM structure 102 reduces the cost commensurately, by about 30%.

Turning to the compact electronic power assembly 401, in some implementations, the chip assemblies 104 are rotated 90 degrees so that the gate and sense terminals are closer to the lead posts 114 and 116. This rotated orientation allows for straight-run wire bonds 407, with no need to bend around corners. With straight-run wire bonds 407, there is also no need for an island such as the island 108 or a cut-out along a perimeter of the DBC 402. In the example shown, the wire bonds 407a and 407b couple the gate terminals of the chip assemblies 104a,b directly to the lead post 116. The wire bond 407c couples the sense terminal of the chip assembly 104b directly to the lead post 114.

The shape and orientation of the F-shaped clip 405 and three wire bonds 407a, 407b, and 407c can then be adapted to the layout of the compact electronic power assembly 401. In some implementations, the tabs of the F-shaped clip 405 have similar widths, e.g., w1, as the widths of the two parallel portions of the main body on either side of the slot 410. In some implementations, the main body of the F-shaped clip has a width w2 that exceeds the tab width w1 by at least a factor of two.

FIG. 5B is a top side plan view of the compact power module 450 shown in FIG. 4B, according to a third implementation of the present disclosure. Turning to the compact electronic power assembly 451, in some implementations, the chip assemblies 104 are rotated 90 degrees so that the gate and sense terminals are closer to the lead posts 114 and 116. This rotated orientation allows for straight-run wire bonds 457, with no need to bend around corners. With straight-run wire bonds 457, there is also no need for an intermediate gate pad such as the island 108 or a cut-out along a perimeter of the DBC 402. With the arrangement of wire bonds 457 shown in FIG. 5B, reliability increases by about 10% to about 15% over current designs.

The shape and orientation of the F-shaped clip 455 and two wire bonds 457a, 457b can then be adapted to the layout of the compact electronic power assembly 451. In the example shown, the wire bonds 457a and 457b couple the gate terminals of the chip assemblies 104a,b directly to the lead post 116. The arm 462 of the F-shaped clip 455 couples the sense terminal of the chip assembly 104b to the lead post 114. In some implementations, the tabs of the F-shaped clip 455 are wider than the tabs of the F-shaped clip 405 shown in FIG. 5A. In some implementations, the tabs of the F-shaped clip 455 and the arm 460 can have similar widths, e.g., w1, as the widths of the two parallel portions of the main body on either side of the slot 460. In some implementations, the main body of the F-shaped clip has a width w2 that exceeds the tab width w1 by at least a factor of two.

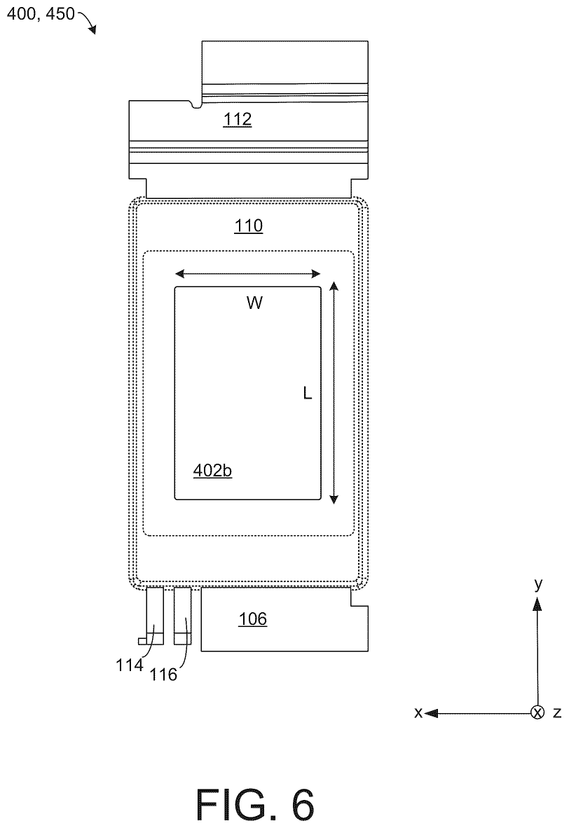

FIG. 6 is a back side plan view of either one of the compact power module 400 or the compact power module 450, as shown in FIGS. 5A and 5B respectively, in accordance with some implementations of the present disclosure. FIG. 6 can be compared with the back side view of the compact power module 100 shown in FIG. 3. FIG. 6 shows exterior parts of the compact power modules 400 and 450, including the encapsulant 110 and other parts that extend out from the encapsulant 110—the mounting bracket 112, the lead frame 106, and the lead posts 114 and 116. The mounting bracket 112 and the lead frame 106 provide mechanical coupling at the ends of the compact power module 400/450, while the lead posts 114 and 116 provide electrical coupling for the compact power module 400/450. The encapsulant 110 exposes the DBC 402 through openings in the encapsulant 110. In some implementations, the two-layer DBC 402 is disposed in an opening in the encapsulant 110 so that the ceramic layer 402b is exposed on the back side of the compact power module 400/450 and the upper DBC layer 402a, serving as a die attach pad, is exposed on the front side of the compact power module 400/450, as shown in FIGS. 5A and 5B. The DBC 402 therefore can radiate heat from both the back side and the front side, acting as a double-sided heat sink to dissipate heat produced by the compact electronic power assembly 401. FIG. 6 shows the DBC 402 is rectangular, having a width s and a length L that is longer than the side s of the DBM structure 102.

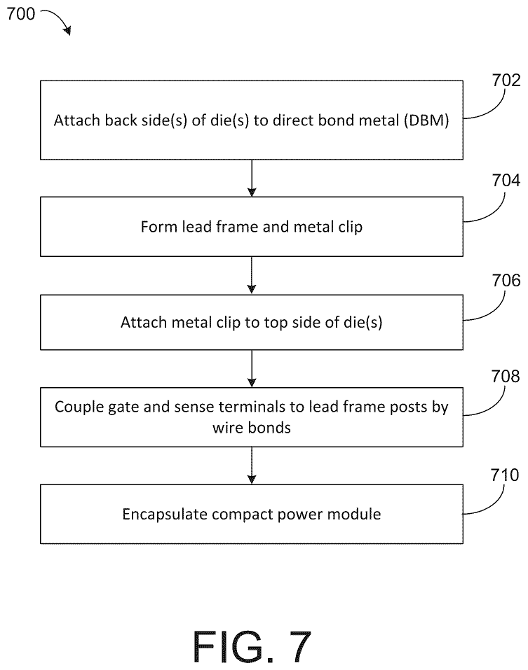

FIG. 7 is a flow chart illustrating a method 700 for fabricating a power module, e.g., the compact power module 100, in accordance with some implementations of the present disclosure. Operations 702-210 of the method 700 can be carried out to form the compact power module 100, according to some implementations as described below, with reference to FIGS. 1, 2, 3, 4A, 4B, 5, 6A, and 6B above. Operations of the method 700 can be performed in a different order, or not performed, depending on specific applications. It is noted that the method 700 may not produce a complete compact power module 100. Accordingly, it is understood that additional processes can be provided before, during, or after method 700, and that some of these additional processes may be briefly described herein.

At 702, the method 700 includes attaching back sides of the chip assemblies 104 to a DBM structure, in accordance with an implementation of the present disclosure. Attaching the chip assemblies can be accomplished using, for example, an adhesive.

At 704, the method 700 includes forming a clip, e.g., the U-shaped clip 105 or one of the F-shaped clips 405/455, attached to the lead frame 106, in accordance with an implementation of the present disclosure. In some implementations, the clip and the lead frame 106 can be formed together from a sheet of rolled copper.

At 706, the method 700 includes attaching the clip to top surfaces of the chip assemblies 104, in accordance with an implementation of the present disclosure. In some implementations, the clip can be soldered to the chip assemblies 104 using, e.g, a silver sintering material.

At 708, the method 700 includes coupling gate and sense terminals of the chip assemblies 104 to the lead frame posts 114 and 116, in accordance with an implementation of the present disclosure. In some implementations, the gate terminals can be coupled directly to the lead frame post 116 by a wire bond. In some implementations, two wire bonds coupled in series can be used to rout connections around a corner. In some implementations, an arm of the clip can be coupled between the sense terminal and the lead frame post 114.

At 710, the method 700 includes an encapsulation operation, in accordance with an implementation of the present disclosure. In some implementations, the encapsulation operation encompasses internal parts including the compact electronic power assembly 101, the wire bonds 107, the island 108, the mounting bracket plate 109, portions of the lead frame 106, portions of the mounting bracket 112, and horizontal portions of the lead frame posts 114 and 116. The internal parts are surrounded with an encapsulant, e.g., an epoxy molding compound, to complete fabrication of the compact power module 100. Encapsulation can be accomplished by, for example, a process of injection molding or a process of transfer molding.

As described above, various implementations of a compact power module can shrink the DBC by about 30% to about 40% while maintaining about the same heat dissipation. By further altering the layout of components mounted on the smaller DBM structure, the number of wire bonds can be reduced, and the routing of the wire bonds can avoid corners. Such changes can increase reliability of the wire bonds by about 10% to about 15%.

It will be understood that, in the foregoing description, when an element, such as a layer, a region, or a substrate, is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application may be amended to recite exemplary relationships described in the specification or shown in the figures.

As used in this specification, a singular form may, unless definitely indicating a particular case in terms of the context, include a plural form. Spatially relative terms (e.g., over, above, upper, under, beneath, below, lower, top, bottom, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor device processing techniques associated with semiconductor substrates including, but not limited to, for example, silicon (Si), silicon carbide (SiC), gallium arsenide (GaAs), gallium nitride (GaN), and/or so forth.

While certain features of the described implementations have been illustrated as described herein, many modifications, substitutions, changes, and equivalents will now occur to those skilled in the art. For instance, features illustrated with respect to one implementation can, where appropriate, also be included in other implementations. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

1. An apparatus, comprising:
a lead frame having a gate lead frame post, a sense lead frame post, and a ground connection;
a direct bond metal (DBM) structure including an insulating layer;
a first die and a second die attached side-by-side to the DBM structure;
a metal clip having a first tab coupling a top side of the first die and having a second tab coupling a top side of the second die to the lead frame using solder; and
an electrical connection coupling a gate terminal of the first die directly to the gate lead frame post.

2. The apparatus of claim 1, further comprising a wire bond coupling a sense terminal of the second die to the sense lead frame post.

3. The apparatus of claim 1, further comprising an arm of the metal clip coupling a sense terminal of the second die to the sense lead frame post.

4. The apparatus of claim 1, wherein the metal clip is connected to the ground connection.

5. An apparatus, comprising:
a lead frame portion;
a direct bond metal (DBM) structure, the DBM structure including a first metal layer, a second metal layer, and a ceramic layer disposed between the first metal layer and the second metal layer,
a first die and a second die attached side-by-side to a die attach pad of the DBM structure;
a U-shaped metal clip having a first tab coupled to a top side of the first die and having a second tab coupled to a top side of the second die, the U-shaped metal clip coupled to the lead frame portion; and
wire bonds including:
a first wire bond coupling a gate terminal of the first die to a gate terminal of the second die, and
a second wire bond coupling the second die to a gate pad.

6. The apparatus of claim 5, further comprising a third wire bond coupling a sense terminal of the second die to a sense lead frame post.

7. The apparatus of claim 5, wherein the wire bonds further include a fourth wire bond coupling the gate pad to a gate lead frame post.

8. The apparatus of claim 7, wherein the first wire bond extends in a transverse direction with respect to the gate lead frame post.

9. The apparatus of claim 5, wherein length and width dimensions of the DBM are each less than 15 mm.

10. The apparatus of claim 5, wherein the wire bonds are made of 300 μm aluminum wire.

11. The apparatus of claim 5, wherein the first die and the second die include silicon carbide (SiC).

12. A method, comprising:
coupling back sides of a first die and a second die to a direct bond metal (DBM) structure;
forming a lead frame and a metal clip;
coupling the DBM structure to a substrate;
coupling the metal clip between top sides of the first die and the second die and a ground plate of the lead frame;
coupling a gate terminal of the first die and a gate terminal of the second die to a first lead frame post; and
coupling a sense terminal of the second die to a second lead frame post.

13. The method of claim 12, wherein coupling the gate terminal of the first die and the gate terminal of the second die to the first lead frame post includes use of wire bonds.

14. The method of claim 13, wherein coupling the gate terminals to the first lead frame post includes coupling the gate terminal of the first die directly to the gate terminal of the second die and coupling the gate terminal of the second die to the first lead frame post.

15. The method of claim 14, wherein coupling the gate terminal of the second die to the first lead frame post includes coupling the gate terminal of the second die to a gate pad and coupling the gate pad to the first lead frame post.

16. The method of claim 12, wherein coupling the sense terminal to the second lead frame post includes use of a wire bond.

17. The method of claim 12, wherein coupling the sense terminal to the second lead frame post includes use of an arm of the metal clip.

18. The method of claim 12, wherein forming the metal clip includes forming the metal clip from copper.

19. The method of claim 12, wherein forming the lead frame includes forming the lead frame from copper.

20. The method of claim 12, further comprising encapsulating the substrate in a package, wherein a back side of the package exposes a lower layer of the DBM structure.
